(19) United States
(12) Patent Application Publication
(10) Pub. No.: US 2026/0242974 A1
(43) Pub. Date: Aug. 20, 2026

(54) SYSTEMS AND METHODS FOR NANOCRYSTAL FABRICATION

(71) Applicant: R. J. DWAYNE MILLER, MISSISSAUGA (CA)

(72) Inventor: R. J. DWAYNE MILLER, MISSISSAUGA (CA)

(21) Appl. No.: 19/160,613

(22) PCT Filed: Aug. 22, 2024
(86) PCT No.: PCT/CA2024/051093

§ 371 Date: Aug. 28, 2025

Related U.S. Application Data
(60) Provisional application No. 63/534,077, filed on Aug. 22, 2023.

(51) Int. Cl. C30B 7/02; G01N 23/20058

(52) U.S. Cl. CPC C30B 7/02; G01N 23/20058

(57) ABSTRACT

Systems and methods are provided for the controlled growth of nanocrystals suitable for electron diffraction measurements for atomic structure determination. A fluidic support structure is contacted with a solution containing a nanocrystal forming material such that the solution is retained thereon. An energy beam, configured to locally induce nucleation and nanocrystal growth, is delivered to spatially-separated locations on the fluidic support structure, thereby forming spatially separated nanocrystals. The fluidic support structure is capable of retaining the solution with a sufficiently thin layer such that the nanocrystals have a submicron thickness suitable for analysis by electron diffraction, without needing transfer of the nanocrystals to a separate holder. The fluidic support structure may include lateral fluidic confinement structures defining a plurality of nanocrystal growth regions, such that each nanocrystal growth region is laterally confined on a submicron to micron scale to isolate growing nanocrystals to create conditions for homogenous nanocrystal growth.

### CROSS-REFERENCE TO RELATED APPLICATION

This application claims priority to U.S. Provisional Patent Application No. 63/534,077, titled “SYSTEMS AND METHODS FOR NANOCRYSTAL FABRICATION” and filed on Aug. 22, 2023, the entire contents of which is incorporated herein by reference.

### BACKGROUND

The present disclosure relates to systems and methods determination of chemical structure via the analysis of nanocrystals, and associated methods of nanocrystalline sample preparation.

Every major chemistry department, material chemistry, pharmaceutical chemistry and associated industry require structures of the final product in a chemical process (full 3D structure at atomic resolution). There are numerous methods by which to determine the final structure of a particular synthetic strategy. These include Nuclear Magnetic Resonance (NMR), Electron Spin Resonances (ESR for systems with unpaired electron spins), infrared methods for some materials (to identify small number of vibrational modes), x-ray diffraction, electron diffraction, neutron diffraction, and real space imaging with either so called cryo-Electron Microscopy (EM) or EM Tomography. NMR has been the work horse in this respect.

Unfortunately, modern synthesis and development of complex novel materials has led to materials with very congested spectra that can no longer be uniquely determined based on NMR, ESR, IR or cryoEM/EM Tomography. Diffraction methods are able to solve structures to atomic resolution, far beyond real space imaging, using single particle methods of EM. The difference is largely due to the great amplification in having over 1010 identical copies of the molecule of interest within the probed volume of a single crystal that greatly amplifies the signal over averaging of single images.

Currently, x-ray diffraction dominates the workflow from synthesis to structure determination as samples are often too difficult to make small enough for electron diffraction (requiring 100 nm thick samples or thinner) or conversely big enough crystals for weakly scattering neutrons. To put the magnitude of the problem in proper context, every major chemistry department in the world houses an x-ray diffraction (XRD) facility at considerable cost considering equipment investments in the multiple million dollar range and associated staff costs.

The problem is further compounded by the fact that x-ray diffraction requires crystals on the scale of 100 microns to 1 mm to enable the use of lab-based instruments for typical x-ray beam diameters. Even the brightest x-ray source, such as X-ray Free Electron Lasers (XFELs), require 10-100 micron thick crystals for handling and positioning in the beam line. This final requirement on the synthesized product means that chemists, material engineers, biochemists and others must start with multigram quantities in synthetic routes and employ large batch processing steps involving class beakers, Erlenmyer flasks, round bottom flasks to mix, heat, condense, isolate and purify each compound on each step in what is often a multistep synthesis, in many cases with over 10 steps to reach the final product state.

The requirement for 100 micron size crystals and sufficient material to make 1000s of crystals to ensure that at least one good crystal is obtained to diffract well enough to provide a high resolution diffraction pattern (not considering powder diffraction for small molecules) leads to the need for large scale processing and associated material costs for a given synthetic route. The amount of material is dictated by the relative weak scattering cross section of x-rays off atoms. In contrast, electrons have very large scattering cross sections, between 104 to 105 larger for typical electron energies relative to x-rays. It is this difference that leads to the requirement of ultrathin, 10-100 nm crystals to enable sufficient electron transmission to observe diffraction. This difference in turn means electron diffraction require orders of magnitude less material in comparison to x-ray and aforementioned other methods.

The reduction in material requirements is particularly important for precious materials such as proteins that require extensive, time intensive, and costly purification steps and are often in very limited supply with respect to source. Similar time intensive and material costs factor into all material synthesis methodologies. Reducing material requirements both reduces environmental impact in use of hazardous materials and dramatically increases throughput as mixing times are reduced commensurately with reduced sample volumes.

A generalized method enabling the use of electron diffraction for structure determination would dramatically increase the throughput for drug and new material discovery while reducing costs and environmental impact. The problem for electron diffraction methods has been the difficulty in preparing samples sufficiently thin to enable the use of electron diffraction. The fragile nature of 100 nm scale crystals and difficulty in mechanical transfer from traditional preparation methods such as microtoming to EM sample holders needs to be appreciated in terms of difficulty and low success rate that has greatly limited the adoption of EM methods for structure determination.

### SUMMARY

Systems and methods are provided for the controlled growth of nanocrystals suitable for electron diffraction measurements for atomic structure determination. A fluidic support structure is contacted with a solution containing a nanocrystal forming material such that the solution is retained thereon. An energy beam, configured to locally induce nucleation and nanocrystal growth, is delivered to spatially-separated locations on the fluidic support structure, thereby forming spatially separated nanocrystals. The fluidic support structure is capable of retaining the solution with a sufficiently thin layer such that the nanocrystals have a submicron thickness suitable for analysis by electron diffraction, without needing transfer of the nanocrystals to a separate holder. The fluidic support structure may include lateral fluidic confinement structures defining a plurality of nanocrystal growth regions, such that each nanocrystal growth region is laterally confined on a submicron to micron scale to isolate growing nanocrystals to create conditions for homogenous nanocrystal growth.

Accordingly, in a first aspect, there is provided a method of fabricating nanocrystals suitable for electron diffraction analysis, the method comprising:
contacting a fluidic support structure with a solution containing a nanocrystal forming material, such that the solution is retained on the fluidic support structure; and
delivering an energy beam to the solution retained on the fluidic support structure at a plurality of laterally spaced regions, the energy beam being configured to locally induce nucleation and nanocrystal growth within the solution, such that within at least one region of the plurality of laterally spaced regions, nanocrystal nucleation and growth is initiated;
wherein the fluidic support structure is configured such that the solution retained thereon is sufficiently thin such that nanocrystals formed within the solution have a submicron thickness suitable for analysis by electron diffraction.

In one example implementation, the method further comprises employing a transmission electron microscope to perform electron diffraction measurements on at least one nanocrystal supported by the fluidic support structure.

In one example implementation of the method, the fluidic support structure is directly employed within the transmission electron microscope for the electron diffraction measurements in the absence of nanocrystal transfer to a separate transmission electron microscope support.

In one example implementation, the method further comprises employing the electron diffraction measurements to infer an atomic structure of the at least one nanocrystal.

In one example implementation of the method, the fluidic support structure is configured to retain the solution thereon with a sufficiently thin layer such that nanocrystals formed within the solution have a thickness between 10 nm and 100 nm.

In one example implementation of the method, the fluidic support structure is configured such that the solution is retained with a submicron to micron thickness.

In one example implementation of the method, the fluidic support structure is configured such that the solution is retained with a submicron thickness.

In one example implementation of the method, a solvent vapour is flowed over the solution retained on the fluidic support structure.

In one example implementation of the method, at least one of a flow rate and a vapour pressure of the solvent vapour is controlled to maintain a thickness of the solution retained on the fluidic support structure. Al least one of a flow rate and a vapour pressure of the solvent vapour may be controlled to maintain a solubility point of the solution retained on the fluidic support structure at supersaturation.

In one example implementation of the method, the fluidic support structure comprises a plurality of lateral fluid confinement structures provided such that each laterally spaced region is at least partially laterally enclosed, and such that nanocrystal growth is spatially confined within each laterally spaced region. The plurality of lateral fluid confinement structures may include a plurality of nanowells.

Each nanowell may include a base region having an aperture defined therein, and a vacuum aspiration subsystem may be interfaced with the fluidic support structure to aspirate solvent through respective apertures of each nanowell. The plurality of lateral fluid confinement structures may include a nanopillar array.

The plurality of lateral fluid confinement structures are configured such that each laterally spaced region has an effective diameter between 100 nm and 5 microns. Adjacent laterally spaced regions may be separated by 100 nm to 5 microns.

In one example implementation of the method, the energy beam is configured to generate bubbles within the solution increasing locally the concentration of solution for initiating nanocrystal nucleation.

In one example implementation of the method, the energy beam is configured such that absorption of the energy beam causes superheating and rapid evaporation to facilitate nanocrystal nucleation and growth.

In one example implementation of the method, the energy beam comprises a plurality of laser pulses. The laser pulses may be femtosecond laser pulses. The energy beam may include infrared laser pulses having a pulse duration less than a thermal diffusion limited cooling time of a solvent of the solution. The fluidic support structure may be configured to absorb the laser pulses and generate heat sufficient for superheating the solution.

In one example implementation of the method, the energy beam is an electron beam.

In one example implementation, the method further comprises directing a probe energy beam onto the plurality of laterally spaced regions, the probe energy beam being configured to generate a signal in the presence of nanocrystals; and employing the signal to monitor nanocrystal growth within the laterally spaced regions. The method may further comprise detecting the signal from a given laterally spaced region; and continuing to deliver the energy beam to the given laterally spaced region until the signal satisfies pre-determined criteria associated with a sufficiency of nanocrystal size for electron diffraction analysis. The method may further comprise detecting an absence of the signal from a given laterally spaced region; and repeating the delivery of the energy beam to the given laterally spaced region.

In one example implementation, the method further comprises directing a probe energy beam onto the plurality of laterally spaced regions, the probe energy beam being configured to generate a signal in the presence of nanocrystals; employing the signal to identify laterally spaced regions containing nanocrystals having a size suitable for electron diffraction; and interrogating the identified laterally spaced regions via transmission electron microscopy.

In one example implementation, the method further comprises subjecting the fluidic support structure to plunge freezing prior to performing transmission electron microscopy.

In one example implementation of the method, the fluidic support structure comprises a TEM grid.

In another aspect, there is provided a system for fabricating nanocrystals suitable for electron diffraction analysis, the system comprising:
a fluidic support structure;
a means for generating and delivering an energy beam to a plurality of laterally spaced regions of said fluidic support structure, the energy beam being configured to locally induce nucleation and nanocrystal growth within a solution containing a nanocrystal forming material when the solution is retained on said fluidic support structure;
said fluidic support structure being capable of retaining the solution thereon with a sufficiently thin layer such that nanocrystals formed within the solution have a submicron thickness suitable for analysis by electron diffraction.

In another aspect, there is provided method of fabricating nanocrystals suitable for electron diffraction measurement, the method comprising:
contacting a fluidic support structure with a solution containing a nanocrystal forming material, such that the solution is retained on the fluidic support structure with a submicron solution thickness;
delivering an energy beam to a plurality of spatially-separated locations within the solution retained on the fluidic support structure,
the energy beam being configured to locally induce nucleation and nanocrystal growth within the solution, such that for at least two of said plurality of spatially-separated locations, a respective nanocrystal having a submicron thickness is formed; and
employing a TEM to perform electron diffraction measurements on at least one nanocrystal residing on the fluidic support structure.

A further understanding of the functional and advantageous aspects of the disclosure can be realized by reference to the following detailed description and drawings.

### BRIEF DESCRIPTION OF THE DRAWINGS

Embodiments are described with reference to the accompanying drawings. In the drawings, like reference numbers can indicate identical or functionally similar elements.

FIGS. 1A and 1B illustrate the use of humidified air to control the solution level to a submicron to micron height within an example fluidic support structure. The crystal growth is necessarily limited to a fraction of the solution thickness.

FIG. 2A illustrates the scanning of an energy beam to generate local bubble formation and cavitation from rapid solution heating at a number of discrete locations within a thin, submicron to micron solution layer, resulting in nucleation and nanocrystal growth at the irradiated locations. The bubble formation leads to a local increase in concentration of the molecule of interest and drives the system from soluble to insoluble limit, leading to the rapid crystallization phase.

FIG. 2B demonstrates how nanocrystals grown within the thin layer of solution may be employed after evaporation of the solvent, for subsequent TEM analysis in the absence of removal and transport of the nanocrystals to a separate TEM holder.

FIG. 2C illustrates the scanning of an energy beam within nanowells of a fluidic support structure to generate local nucleation bubbles and cavitation within nanowells, resulting in local nucleation and nanocrystal growth within the nanowells.

FIG. 2D demonstrates how nanocrystals grown within the nanowells of the fluidic support structure may be employed, after evaporation of the solvent, for subsequent TEM analysis in the absence of removal and transport of the nanocrystals to a separate TEM holder.

FIGS. 2E and 2F illustrate the use of electron beam heating and ultrafast laser pulses, respectively, to achieve a local increase in concentration that results in nucleation and crystal growth.

FIGS. 3A, 3B and 3C illustrate, via the crystallization phase diagram, how bubble formation and cavitation causes a local increase in analyte concentration that results in a local transition within the phase diagram from a stable state to an unstable state associated with nucleation and growth of nanocrystals, and the resulting transition to a final state in which the nanocrystals remain stable.

FIG. 4 illustrates an example method of removal of solvent after nanocrystal formation, to enable transfer to the high vacuum environment of the TEM with the example method employing pressure-assisted removal of the solvent.

FIG. 5 illustrates an example embodiment in which nanocrystal growth is monitored via detection of optical signals produced by nanocrystals in response to illumination, illustrating an example optical detection modality in the case shown involving the detection of second harmonic generation (SHG). Other optical methods sensitive to changes in index of refraction such as dynamic light scattering (DLS) can also be used to probe nucleation and formation of nanocrystals to optimize growth and nucleation conditions.

FIG. 6 is a flow chart illustrating an example method of fabricating nanocrystals for electron diffraction measurements within a fluidic structure that is suitable for subsequent TEM analysis.

FIG. 7A shows a cross-sectional view of an example fluidic support structure that employs an array of nanowells to confine a solution and support the growth of nanocrystals with suitable dimensions for electron diffraction measurement. This structure is one example of embodiments that would allow rapid solvent removal after nanocrystal growth per FIG. 4.

FIG. 7B shows a top view of the nanowell array portion of the example device shown in FIG. 7A.

FIGS. 7C, 7D and 7E illustrate an alternative method involving initiation of nanocrystal nucleation and formation in a solution layer residing above a nanostructure array, followed by aspiration and entrapment of the nanocrystals in the nanostructure array.

FIG. 8A shows an isometric view of an example nanopillar array, where the nanopillars have a submicron to micron height configured to confine a submicron to micron layer of solution, and a spacing configured to support the growth of nanocrystals with suitable dimensions for electron diffraction measurement. Rapid freezing upon removal of solvent enables use in the vacuum conditions needed for TEM analysis.

FIG. 8B shows a top view of an example fabricated nanopillar array.

FIG. 8C shows an example workflow for contacting a solution with a nanopillar array of an example fluidic structure to form a submicron to micron solution thickness with the use of lateral vapour flow to control and/or maintain the solution height within the fluidic structure as an additional means to ensure proper liquid thickness over the nanopillar array, without requiring an enclosure or a second window.

FIG. 9 illustrates an example system for fabricating nanocrystals within a fluidic structure that is suitable for subsequent TEM analysis.

FIG. 10 illustrates an example environmental control subsystem for controlling and maintaining a desired solution level within the fluidic support structure to facilitate the growth of nanocrystals with dimensions suitable for electron diffraction.

### DETAILED DESCRIPTION

Various embodiments and aspects of the disclosure will be described with reference to details discussed below. The following description and drawings are illustrative of the disclosure and are not to be construed as limiting the disclosure. Numerous specific details are described to provide a thorough understanding of various embodiments of the present disclosure. However, in certain instances, well-known or conventional details are not described in order to provide a concise discussion of embodiments of the present disclosure.

As used herein, the terms “comprises” and “comprising” are to be construed as being inclusive and open ended, and not exclusive. Specifically, when used in the specification and claims, the terms “comprises” and “comprising” and variations thereof mean the specified features, steps or components are included. These terms are not to be interpreted to exclude the presence of other features, steps or components.

As used herein, the term “exemplary” means “serving as an example, instance, or illustration,” and should not be construed as preferred or advantageous over other configurations disclosed herein.

As used herein, the terms “about” and “approximately” are meant to cover variations that may exist in the upper and lower limits of the ranges of values, such as variations in properties, parameters, and dimensions. Unless otherwise specified, the terms “about” and “approximately” mean plus or minus 25 percent or less.

It is to be understood that unless otherwise specified, any specified range or group is as a shorthand way of referring to each and every member of a range or group individually, as well as each and every possible sub-range or sub-group encompassed therein and similarly with respect to any sub-ranges or sub-groups therein. Unless otherwise specified, the present disclosure relates to and explicitly incorporates each and every specific member and combination of sub-ranges or sub-groups.

As used herein, the term “on the order of”, when used in conjunction with a quantity or parameter, refers to a range spanning approximately one tenth to ten times the stated quantity or parameter.

Unless defined otherwise, all technical and scientific terms used herein are intended to have the same meaning as commonly understood to one of ordinary skill in the art. Unless otherwise indicated, such as through context, as used herein, the following terms are intended to have the following meanings:

As used herein, the phrase “submicron” refers to a range between 100 nm and 1 micron.

As used herein, the phrase “submicron to micron” refers to a range between 100 nm and 5 microns.

As used herein, the phrases “nanocrystal forming material” and “target nanocrystal forming material” refers to a material which, when dissolved in a suitable solvent and subjected to appropriate nucleation conditions, is capable of crystallization from the solution under appropriate conditions. The nanocrystal forming material may have been obtained, for example, from a chemical synthesis, or purification of proteins or other extracted materials from various sources.

As described above, conventional approaches to structural analysis that employ x-ray diffraction are limited by the need for large and expensive infrastructure and the requirement for large and thick crystals that places high demands on synthesis methods.

In principle, electron diffraction could provide an alternative method of structural determination that overcomes the aforementioned problems associated with x-ray diffraction. The scattering cross section of electrons is between 104-106 larger than that of x-ray diffraction, depending on electron energy relative to 10 KeV x-ray photons typically used for x-ray diffraction. For 100 KeV to 300 KeV electrons, the difference in cross section is approximately 105. For comparison, x-rays pass through the human body, while electron diffraction requires samples of 100 nm thick or thinner to have sufficient electron transmission to generate an observable diffraction pattern. This extremely large difference in scattering cross section means that in principle, 105 less material should be needed for electron diffraction using typical electron sources, relative to x-ray diffraction, in directing a chemical synthesis or exploring fabrication of new materials or drug development.

This difference means that material requirements could be reduced from gram quantities to microgram quantities, within the limit of easy-to-use balances for weighing out the materials for proper starting ratios. This very small mass requirements means that chemistry could finally evolve away from beakers and flasks for macroscale processing to true lab-on-a-chip technology. Rather than employing liter quantities, one could use small volumes such as microliter volumes that are routinely easy to dispense by hand or robotics.

This extremely small volume of material would mix much faster, which would speed up the time to work up a reaction step by orders of magnitude. Synthetic steps requiring days to weeks could be done in hours to seconds. The speed up, except for exceptionally high thermal barriers, would greatly increase throughput in drug discovery to give just one important application. Perhaps most important, the small amount of material employed would greatly increase safety as very expensive fume hoods could be replaced with small scale traps with low-cost pumps to eliminate or reduce the need to vent chemical fumes to the atmosphere. Furthermore, the cost of materials can potentially be reduced by a factor of up to approximately 105, which by itself will greatly increase the number of different synthetic processes can be explored and speed up of chemical/materials research by orders of magnitude.

However, despite these clear advantages of electron-diffraction-based structural analysis, the absence of practical and cost-effective methods of preparing nanocrystals with sizes and thicknesses suitable for electron diffraction has limited its widespread adoption.

One significant challenge faced by prior attempts to realize this goal has involved the need to transfer nanocrystals onto a suitable transmission electron microscopy (TEM) support for analysis without losses. Indeed, prior attempts have been hindered by the challenge of handling, during transfer and transport, extremely small microgram scale amounts of nanocrystal samples to provide nanocrystals for final structure verification.

It has generally been found that handling of the material in growing crystals and transporting to a transmission electron microscope (TEM) sample support grid needed for the electron diffraction/structure determination step leads to major losses both in recovered material and in time required in screening crystals due to the mechanical means needed to reduce crystal sizes to nanoscale thicknesses. For example, the current process involves microtoming macrocrystals, using a diamond knife to cut off 100 nm thick crystals, with generally low success rates in both cutting and fishing out useable crystals for electron diffraction (<1% including crystal screening and solubility issues in the liquid water basin used to catch and float the microtomed crystal flakes). This overall approach requires similar quantities of material as x-ray diffraction analysis, thus, losing the major advantage in scaling down the amount of material required for electron diffraction determination of structure.

The present inventors thus set out to overcome this barrier by developing systems and methods for preparing nanocrystals with suitable dimensions for electron-diffraction-based structure determination in a format that avoids the need for nanocrystal transfer to a separate TEM support prior to TEM analysis, and therefore avoids the impact of nanocrystal transfer losses that have plagued previous attempts to reliably fabricate nanocrystals for electron-diffraction-based structural analysis.

The present inventor realized that this goal could be achieved by employing a fluidic support structure capable of supporting a solution of a nanocrystal-forming material with micron to submicron thickness, and by controlling the spatially-separated nucleation of nanocrystals such that nanocrystals are formed with dimensions appropriate for electron microscopy, and where the fluidic support structure is capable of direct use within a TEM, without requiring nanocrystal transfer to a separate TEM support. Accordingly, the systems, methods and devices of the present disclosure provide fluidic devices that facilitate the in-situ fabrication of nanocrystals and the preparation of such nanocrystals for direct TEM analysis for high throughput structure determination, while avoiding handling losses and employing small volumes of nanocrystal-forming source material.

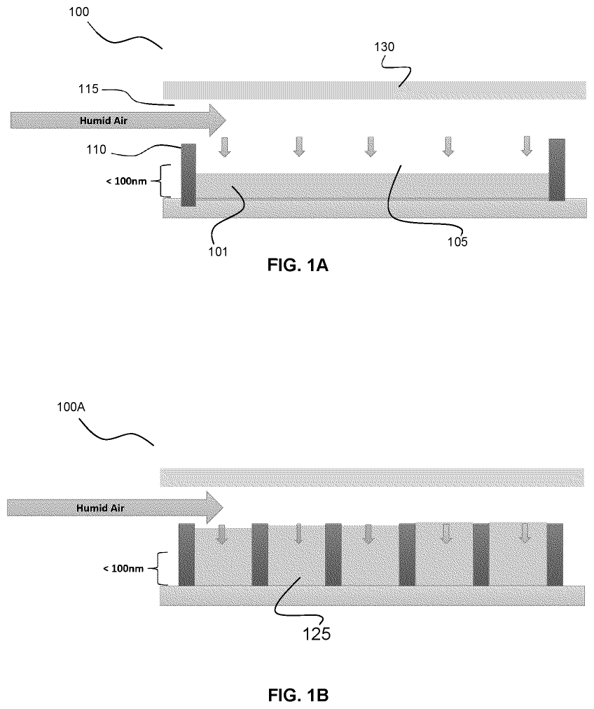

Two examples of suitable fluidic support structures configured to form and maintain a submicron to micron solution thickness are shown in FIGS. 1A and 1B. FIG. 1A shows a cross-sectional view of an example fluidic support structure 100 having an internal reservoir 105 bounded by a peripheral wall 110, a top cover 130, and an internal flow channel 115. The internal reservoir 105 is initially at least partially filled with a solution 101 containing a solvent in which a nanocrystal-forming material is dissolved. A mixture of air (or another suitable inert gas) and a vapour form of the solvent (e.g. water or another solvent) is flowed through the internal channel at a rate suitable for maintaining a submicron to micron thickness 101 of the solution. The thickness of the solution may be monitored, for example, optically, through the top cover 130.

FIG. 1B illustrates an alternative example implementation 100A of a fluidic support structure that includes an array of nanowells 125, with each nanowell having submicron to micron height, where the solution height is maintained within the nanowells via the flow of a gas/vapour mixture (e.g. humidified air). In some example embodiments, the nanowells have a submicron diameter, while in other example embodiments, at least some of the nanowells have a diameter ranging from 1 to 2 microns, or a diameter ranging from 1 to 3 microns, or a diameter ranging from 1 to 4 microns, or a diameter ranging from 1 to 5 microns.

The example fluidic support structures (flow cells) shown in FIGS. 1A and 1B allow the controlled flow of the supernatant solvent vapour to keep the solution at the solubility point just at supersaturation-poised to undergo crystallization. This configuration enables the growth of a plurality (e.g. thousands) of nanocrystals with dimensions ranging from 10-100 nm thick and up to micron to 10 micron in lateral dimensions.

To ensure the crystal growth is constrained to 100 nm thickness, the above solution thickness may be constrained to 100 nm to 1 micron thickness by flowing vapor of the host solvent at the right vapor pressure for a given temperature to give the desired liquid thickness. Solution liquid layer thickness is thus controlled by flow of solvent vapor and degree of vapour saturation.

Both humid air control and the nanostructures (e.g., nanopillar or nanowell arrays) can be beneficial in retaining the thickness of the nanocrystal forming solution on the fluidic support structure. The fluidic support structure (optionally implemented as a liquid cell) can be filled with the nanocrystal-forming solution according to various example methods, including, but not limited to, through direct liquid injection and drop-casting. Initially, the thickness of the nanocrystal-forming solution may be relatively thick (e.g. 1-5 microns). In some example implementations, control of the flow of the humid air flow (and optionally control of the pressure and/or solvent vapour pressure inside the cell) can enable the nanocrystal-forming solution thickness (height) to be thinned down to approximately 100 to 200 nm via evaporation, condensation, and/or displacement. Geometrical factors, such as nanopillar height and spacing (or diameter and depth in the case of nanowells), along with surface tension characteristics (e.g., water repellency on the nanostructures), can be employed to control how vapor selectively condenses between the nanopillars or within the nanowells, optionally such that no nanocrystal-forming solution remains above the top of the nanostructures. The seeding energy source targets the contained solution, forming a shower of nanocrystals defined by the nanostructure. The remaining solution can then be removed using the humid air control device (i.e. aspiration), as described in further detail below.

Crystal thickness control can be based on control of the thickness of the host solvent for supporting crystal growth. The crystal thickness will be less than the liquid thickness by virtue of the need for physical transport of molecules to the nucleation site and ensuing support of crystal growth. This extremely thin liquid layer geometrically constrains the crystal growth to less than the thickness of the liquid layer. The crystal cannot be thicker than the liquid that is transporting the molecules to and from the nucleation site, allowing exchange of molecules at a nucleation site, to allow crystal growth. This aspect of the present disclosure ensures sample thicknesses ideal for electron diffraction, without requiring mechanical handling, microtoming, or other procedure currently employed to generated nanocrystals of suitable thickness for electron structure determination.

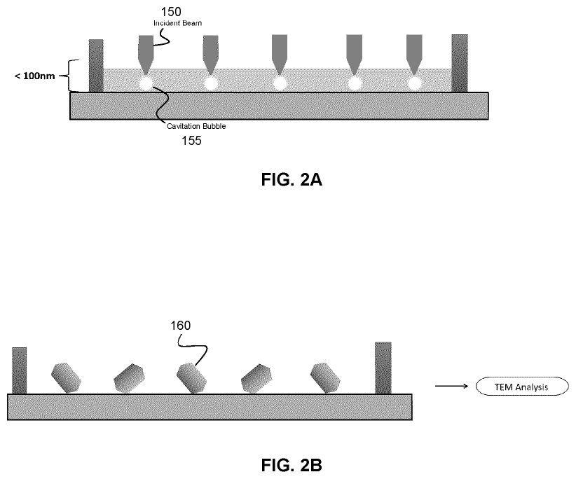

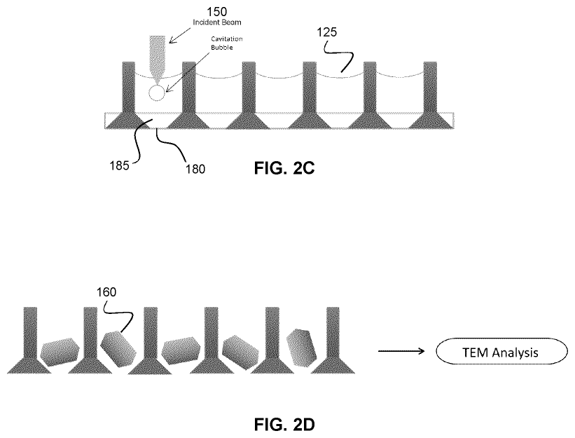

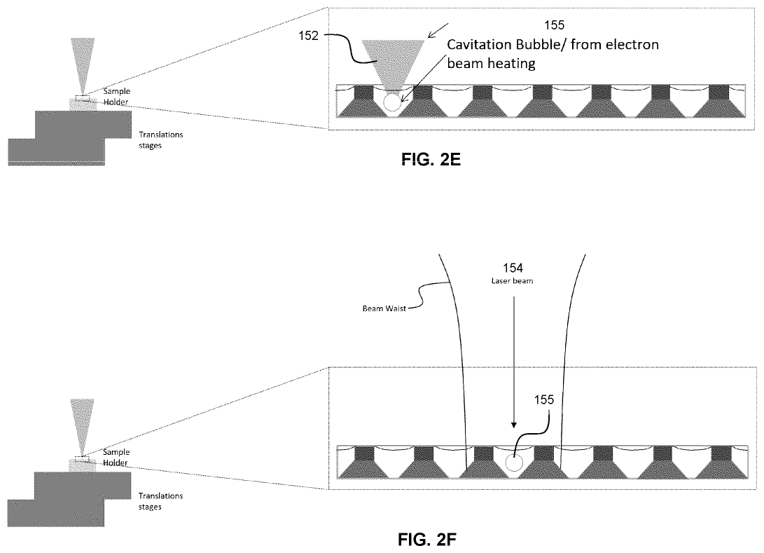

Nanocrystals are formed within the submicron to micron-thick fluid volume(s) supported on the fluidic support structure by the controlled local delivery of energy to selected spatially-separated fluid regions, where the energy is sufficient to cause nucleation for crystal growth. For example, FIG. 2A illustrates the scanning of an energy beam 150, which could be a laser or an electron beam, among a plurality (e.g. array) of spatially-separated locations within the submicron to micron fluid layer residing on a fluidic support structure, similar to the embodiment shown in FIG. 1A. In the non-limiting example implementation in the figure, the thickness of the solution retained on the fluidic support structure is less than 100 nm, such as between 20 nm and 100 nm. The energy beam generates local nucleation (e.g. bubble formation and cavitation 155 to lead to locally driven cavitation-induced nucleation) at each spatially-separated location, thereby resulting in local nucleation and nanocrystal growth at each location. Nanocrystal nucleation is localized in the region defined by the energy beam diameter. The energy beam can be scanned to create a plurality of such regions, for example, to maximize the number of crystals and thereby statistically increase the signal to noise ratio and structural resolution of subsequent electron diffraction measurements. Details such as location of water and hydrogen atoms can be important for understanding structure and require the highest resolution possible to be observed. The distance between adjacent irradiated locations is sufficiently large to permit the growth of nanocrystals with lateral dimensions suitable for electron diffraction.

While FIG. 2A does not show the top cover and the flow of a gas/vapour mixture, it will be understood that these features may be included to control and/or maintain the height/level of the solution during energy beam scanning for locally-induced nucleation. After removal of the residual solvent, the resulting structure can be employed for electron diffraction measurement by a transmission electron microscope (TEM), as shown in FIG. 2B. Beneficially, given the submicron to micron solution thickness, the TEM analysis may be performed on the nanocrystals 160 retained within the fluid support structure without requiring the removal and transport of the nanocrystals to a separate TEM holder.

Likewise, FIG. 2C illustrates the scanning of an energy beam 150 within nanowells 125 of a fluidic support structure similar to that shown in FIG. 1B to generate local nucleation (e.g. cavitation-induced nucleation) within the nanowells, thereby resulting in local nucleation and nanocrystal growth within the nanowells. In the example fluidic support structure shown in FIG. 2C, the base region 185 of each nanowell 125 includes an aperture 180 that is sufficiently small to retain the solution within the nanowell. As also shown in the figure, the base region 185 of the nanowell 125 may have a truncated pyramid shape (trapezoidal in cross section), such that the distal aperture 180 is smaller than an upper opening of the nanowell. While the figure does not show the top cover and the flow of a gas/vapour mixture, it will be understood that these features may be included to control and/or maintain the height/level of the solution during energy beam scanning for locally-induced nucleation. It will be understood that nucleation process will vary from sample to sample with varying barriers to forming nucleation sites. Once a nucleation site is formed there is generally very fast, near diffusion limited growth of the crystals.

After removal of the residual solvent, the resulting structure can be employed for electron diffraction measurement by a transmission electron microscope (TEM), as shown in FIG. 2D. Beneficially, the TEM analysis may be performed on the nanocrystals retained within the fluid support structure without requiring the removal and transport of the nanocrystals to a separate TEM holder.

The fluidic support structure shown in FIGS. 1B, 2C and 2D includes a plurality of nanowells, which are local fluidic confinement structures that are configured to establish a spatially-separated set of nanocrystal growth regions, with each nanocrystal growth region having a lateral extent (in the present case, a nanowell diameter) that is selected to limit the lateral size of nanocrystals, such that the combination of the submicron to micron solution thickness and the lateral confinement of the nanocrystal growth region limits the growth of seeded nanocrystals such that the nanocrystals grown within the nanocrystal growth regions have spatial dimensions that are sufficiently small for analysis via electron diffraction (without the need to fragment the grown nanocrystals).

In some example embodiments, as illustrated in FIG. 2E, an electron beam 152 can be employed to locally heat the solution, similar to laser initiation, creating bubbles 155 to locally increase the concentration of the nanocrystal-forming material, such that conditions suitable for nanocrystal nucleation and growth are locally achieved within the irradiated region.

In other example embodiments, as illustrated in FIG. 2F, ultrafast laser pulses 154 are focused onto the submicron to micron solution layer to locally heat the solution and cause a local increase in concentration (e.g. via cavitation 155) that is sufficient to result in nucleation and nanocrystal growth. The ultrafast laser pulses 154 involve high enough peak power to cause multiphoton absorption to ensure depositing sufficient energy and associated solution heating for even transparent solutions. This procedure facilitates rapid scanning to form crystals with known locations and spacing and eliminates or reduces the presence or likelihood of nanocrystal growth problems including the twinning of crystals and polycrystal formation, which can cause difficulties when solving crystal structures.

In some example implementations, to ensure nucleation occurs and to control spatial location of crystals to avoid overlap of crystals and overlapping or twinning of crystals, the laser is used to excite the solvent host for the crystal growth to lead to rapid evaporation and realization of very strong driving conditions, free energy relations, to spatially initiate crystallization. The laser can be a femtosecond laser whereby the wavelength is tuned to not be resonant with the liquid or molecules involved in crystallization. While the laser beam can only be focused down to micron dimension, the nonlinear interaction and nucleation seeding occur within the beam focus and can be controlled to occur in a single well either statistically or by the nonlinearity of the process-to effectively provide a nucleation “beam” much smaller than the laser beam intensity profile.

Energy may be deposited into the solution for crystallization by multiphoton absorption, multiphoton ionization and recombination of photoemitted electrons, leading to rapid deposition of heat. The amount of energy deposited is controlled by the laser pulse energy to drive a phase transition to form gas bubbles that reduces the solvent fraction and gives an impulsive change in the solution concentration to shock the system to form a nucleation site. This step drives the system to very strong driving conditions, free energy, that is well beyond what could be done by exploiting temperature and pressure normally used for slow evaporation to induce crystallization (and conventional growth of large crystals). This rapid super heating procedure is designed for rapid crystallization growth, as uniformly as possible, to generate hundreds to thousands of nanocrystals for electron diffraction structure determination. This step ensures suitably-spaced-out nucleation sites and growth of micron to 10 micron scale area crystals with thickness in the order of 100 nm, suitable for electron diffraction.

The above process for femtosecond lasers has the advantage in that for most applications use of femtosecond pulses at common fundamental wavelengths of 800 nm in terms of Ti:sapphire lasers or 1 micron for Nd based femtosecond lasers (defined to have pulses shorter than 1 picosecond) are not absorbed by most solvents or molecules of interest for drug development or even proteins or other chromophores. Alternatively, a short pulse infrared (IR) laser with wavelengths absorbed selectively by the host solvent can be used to superheat and spatially evaporate solvent and driven nucleation growth. The IR pulse duration should be less than the time for thermal diffusion out of the diameter of the excitation beam used. For IR typical focusing, this will be on the 100 micron scale, near diffraction limit in IR range, for which the thermal diffusion time to reduce the temperature imposed to drive rapid solvent evaporation, will decay within 10 milliseconds for most solvents. The IR pulse duration should therefore be approximately 10 microseconds or less to impulsively drive nucleation by rapid solvent evaporation by superheating.

Alternatively, a laser tuned to the absorption of underlying substrate can be used to superheat the solution in contact to create bubbles and drive nucleation. The laser can be tuned in the visible to be resonant with coatings incorporated on or into the fluidic support structure (and/or incorporated on or into a TEM sample grid integrated with the fluidic support structure) such as, for example, an Au or other metallic coating where there is significant absorption of green (530 nm) light within 10-100 nm of the surface to lead to large local temperature increases to superheat the solution in contact with it. This example is not intended to be limited to absorbing metal coatings but could include carbon, graphene layers, or other suitable strongly absorbing material to confine the absorbed laser energy to within the surface/solvent contact with the absorption depth being less than 100 microns to ensure thermal diffusion and heating of the solvent occurs fast enough to drive nucleation, and persists long enough for thermal diffusion associated cooling to not limit crystal growth.

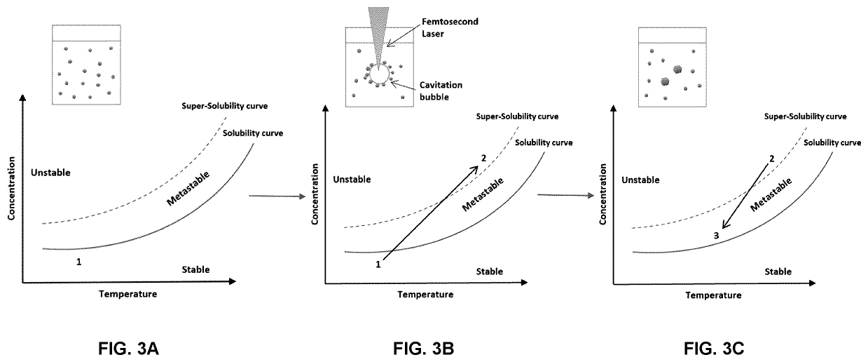

FIGS. 3A, 3B and 3C illustrate, via the crystallization phase diagram, how cavitation causes a local increase in analyte concentration that results in a local transition within the phase diagram from a stable state to an unstable (labile) state associated with nucleation and growth of nanocrystals, and the resulting transition to a final state in which the nanocrystals remain stable. This figure explains the physics/chemistry exploited to stimulate crystal growth at desired locations. Normally nucleation is a random, rare, process, such that when a nucleation site forms, it quickly takes over, depleting concentration for other possible nucleation events in its wake, with the resulting crystal growing to micron and larger scales not suitable for electron diffraction and often there is polycrystalline growth. By laser or electron beam removal of solvent in the form of cavitation/bubble to yield very local super heating, there is exponential growth of a nucleation site at one or more locations, which may lead to one or more nucleation sites randomly distributed within the excited volume. By scanning with a well-separated pattern to prevent nucleation depletion of compound of interest, it is possible to generate a homogeneous distribution of nanocrystals. The spacing is controlled by the laser or electron beam and the thickness by control over the liquid/solution phase thickness. The crystal will deplete the concentration near the surface region without exceeding the thickness of the liquid layer.

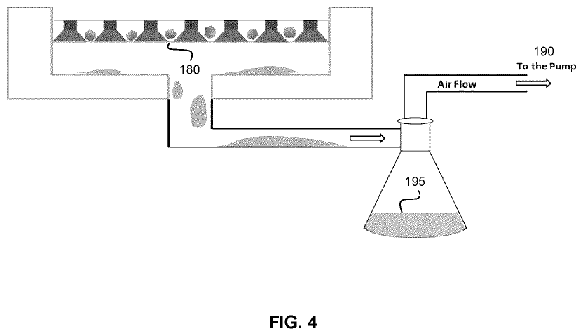

As shown in FIG. 4, following nanocrystal formation, the residual solvent may be removed prior to TEM analysis, which may be beneficial to reduce background scatter from obscuring the sought after diffraction pattern. Aspiration, e.g. generated by a pump 190 may be employed to quickly remove solvent 195 to reduce background scatter, while leaving some “mother liquor” in the wells to conserve crystals from dehydration/cracking. The fluidic support structure can be transferred (e.g. immediately transferred) to a TEM or the whole system of aspiration could be performed within the TEM. While the figure shows an example method of solvent removal that employs pressure-assisted removal of the solvent through one or more apertures 180 within the surface of the fluidic support structure, it will be understood that alternative approaches may be employed to achieve solvent removal.

As described above, FIGS. 1A and 1B show example devices and methods that employ the use of a humidified gas to control and/or maintain the height (level) of the solution within the fluidic support structure. In some example embodiments, however, the device and method may be implemented without the use of the humidified gas. For example, the fluidic structures shown in FIGS. 1A, 1B, or variations thereof, may be contacted with the solution such that the internal reservoir(s) are filled with the solution to a submicron to micron height. The device may be configured, for example, by selecting a suitable material or surface treatment such that the submicron to micron height is achieved viameniscus pinning effects.

The scanning of the energy beam to generate local nucleation and spatially-separated nanocrystal growth may be performed over a time duration that is sufficiently fast to avoid substantial evaporation of the liquid (e.g. a reduction in height of less than 10%, less than 15%, less than 20%, less than 25%, less than 30%, less than 40%, or less than 50%. This may be achieved, for example, by employing a sufficiently fast scanning rate and/or selecting a sufficiently small number of scanned locations. For example, for an ultrafast laser having a pulse repetition rate of 1 kHz, the laser beam can be scanned over 10,000 locations in 10 seconds, a time that may be sufficiently fast to avoid substantial evaporative loss. Additionally or alternatively, the one or more fluidic reservoirs, once filled with the solution to form a submicron height, may be covered during the scanning of the energy beam to prevent or reduce evaporative loss. Furthermore, in some example implementations, the fluidic support structure can be brought into contact with a chamber containing an additional volume of the solution, such as pipette delivery tip or an on-chip reservoir (e.g. via a fluidic channel) to allow the solution to maintain the submicron liquid height within the one or more internal reservoirs.

Furthermore, while some of the methods disclosed herein employ the removal of all or a substantial portion of the solvent within the internal reservoir(s) prior to electron diffraction, it will be understood that in other example embodiments, plunge freezing, or another suitable freezing method, may be employed to freeze the solution after nanocrystal formation, such that thin submicron layer of liquid within the fluidic support structure, sufficiently thin for electron diffraction, is maintained in a frozen state during electron diffraction measurements. Device configurations that are absent of a top cover, or for which the top cover is removable, may be compatible with plunge freezing. Plunge freezing, a cryo-preparation method, may be performed by plunging the fluidic support structure into liquid ethane/liquid N₂ to create amorphous ice (approximately the same density as liquid water). Plunge freezing can avoid the need for the top cover (window), which is generally much thicker than C coated Au grids for TEM imaging.

The step of plunge freezing will arrest any further nanocrystal growth. It is known that plunge freezing does not change the crystal diffraction quality and can lead to an improvement in crystal diffraction quality, as it freezes out motions that are involved in electron induced damage during TEM imaging/diffraction. The use of plunge freezing (or another suitable cryo-prep method) freezes out most of the motions so that approximately a factor of 10 or more higher electron dose is possible with cryo-preparation when compared to room temperature electron diffraction. Indeed, it has been found that for cryo-prepared samples, one can use 8 e/Å², while for room temp samples, an electron dose of less than 1 e/Å² can only be achieved. The higher the number of electrons used for diffraction/imaging, the brighter the diffraction image, and better SNR to give higher spatial resolution.

In some example implementations, the presence of nanocrystals can be detected and/or the growth of nanocrystals can be monitored using a suitable monitoring modality. The probe could also be a diffraction limited laser beam where the observable is dynamic light or Mie scattering by which the crystal size in the 100 nm range can be detected. In another embodiment, screening can be conducted with an environmental SEM or in the TEM directly, using real space imaging. Non-limiting examples of optical modalities for the detection of nanocrystals and/or the monitoring of nanocrystal growth include second harmonic generation (SHG) and dynamic light scattering (DLS).

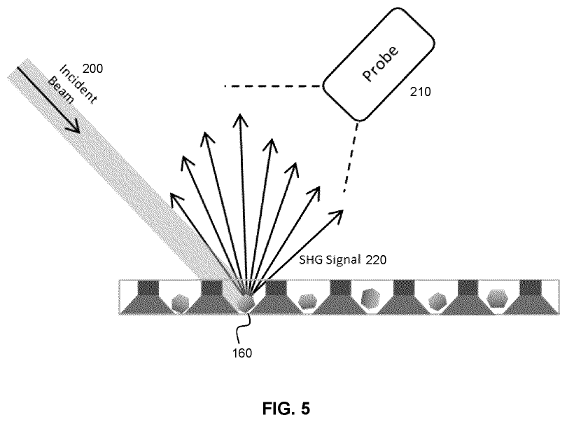

FIG. 5 illustrates an example embodiment in which nanocrystal growth is monitored via detection of aforementioned optical signals produced by nanocrystals 160 in response to illumination via an incident (probe) energy beam 200, illustrating an example optical detection modality involving the detection, via detector (probe) 210, of second harmonic generation (SHG) signal 220. This process can only occur with crystals as it breaks the full symmetry of solution phase.

These monitoring capabilities will show the onset of nanocrystal growth through abrupt changes in SHG or DLS emanating from the solution. This onset of SHG or DLS monitoring signal is based on intensity and subsequent TEM observation of the crystals directly allows control and/or optimization of crystal growth conditions with regard to laser excitation and other adjustable parameters, such as, for example, solvent, concentration, and temperature to maximize yield of nanocrystals. For example, experiments (e.g. matrix studies) can be performed with different values of one or more parameters, and signals detected while performing nanocrystal monitoring can be processed and employed to determine suitable values of the one or more parameters.

In some example implementations, after having scanned an energy beam to cause local nucleation and promote local nanocrystal growth, a nanocrystal detection modality can be employed to detect the presence or absence of nanocrystals within at least a subset of the spatial locations that were energized. At a location where a nanocrystal was not formed, local irradiation can be repeated, optionally with a higher intensity.

In other example implementations, a nanocrystal monitoring modality can be employed to monitor the growth of nanocrystals, such that growth can be reduced or arrested once the nanocrystals have spatial dimensions suitable for electron diffraction (e.g. a thickness in the range of 10-100 nm). These conditions can be determined by employing SHG signal intensity to determine a yield of crystals and/or a rate of formation to estimate size, for example, based on a predetermined relationship between SHG signal intensity and these parameters. Similarly, DLS signals can be directly correlated to the size of the scattering particle from the increased spatial extent of diffuse light scattering by measuring directly the spatial profile of the transmitted laser probe, a monitoring method used extensively for determining nanoparticle sizes such as polymer size.

As a further example, an environmental SEM capable of ambient pressure observations, in combination with either electron beam or laser beam to induce nucleation, can be used to directly observe crystal growth to provide or determine suitable criteria for arresting crystal growth. With this calibration and correlation to crystal size, the further growth of the crystals beyond the acceptable thickness range can be rapidly arrested. For example, nanocrystal growth can be arrested by plunge freezing. In other example implementations, a monitoring or detection means may be employed, after removal of the solvent or after plunge freezing the fluidic support structure, to screen for spatial locations with nanocrystals having spatial dimensions suitable for electron diffraction, such that the identified locations can be stored and employed to select appropriately sized nanocrystals for electron diffraction measurements during use of a TEM.

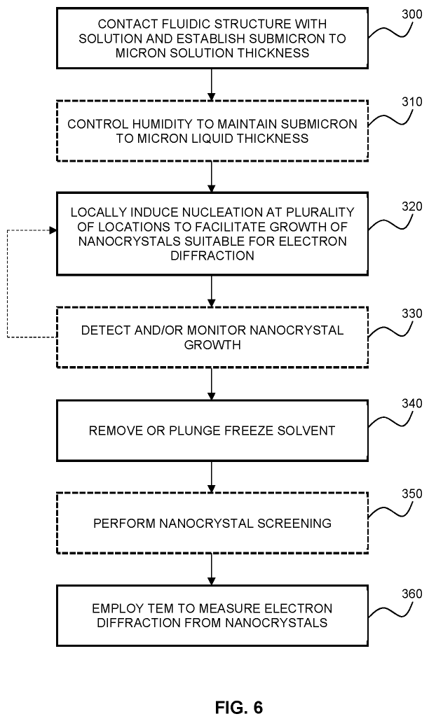

FIG. 6 is a flow chart illustrating an example method of fabricating nanocrystals within a fluidic structure that is suitable for subsequent TEM analysis. In step 300, a fluidic support structure, such as the examples shown in FIGS. 1A and 1B, is contacted (e.g. wetted) with a solution containing a nanocrystal-forming material, and a submicron to micron height of the solution is established, as described above, with the solution residing in one or more reservoirs. In example embodiments in which an internal gas flow channel is incorporated, a gas/solvent vapour mixture is flowed over the one or more reservoirs to control or maintain the submicron to micron height of the retained solution, shown as optional step 310. A local energy delivery means, such as a scanned energy beam, is then employed to locally promote, at a plurality of spatially-separated locations, conditions suitable for achieving nucleation and nanocrystal growth, as shown at step 320. Nanocrystal growth may be detected and/or monitored, and the resulting signals may be employed to actively control the local nucleation and growth process, such as repeating local irradiation when a nanocrystal is not detected at a given location that was irradiated, or subjecting the fluidic support structure to conditions that arrest nanocrystal growth after determining that the nanocrystals have reached a size suitable for electron diffraction measurements, as shown at optional step 330. The solvent may then be removed, or frozen via cryo-processing (e.g. plunge freezing), as shown at step 340. The presence or absence of nanocrystals, or the determination of spatial locations with nanocrystals having a size suitable for electron diffraction, may optionally be determined via a suitable nanocrystal monitoring/screening means, as shown at step 350, before employing a TEM to perform electron diffraction measurements on the nanocrystals in step 360. The preceding steps can be executed in rapid succession (e.g. minutes) to produce nanocrystals ideal for electron diffraction, specifically intended for serial electron diffraction, directly on TEM sample grids or sample holders without any mechanical handling losses. The fluidic support structure can be configured to be of the correct dimensions to insert directly into the TEM for electron diffraction determination of the molecular structure.

Accordingly, various example embodiments of the present disclosure provide a means to define a submicron to micron liquid/solution phase layer and to locally induce spatially distributed nucleation to grow nanocrystals having submicron spatial dimensions in thickness on a device that is compatible with TEM. Such embodiments facilitate the direct fabrication of nanocrystals of appropriate dimensions for electron diffraction, avoid the need for crystal transfer prior to performing electron diffraction, and enable the use of much smaller amount of nanocrystal forming material than conventional approaches to nanocrystal preparation described above. For example, present example devices and methods can be employed to grow a collection of individual and spatially-separated nanocrystals, residing in selected locations on a fluidic support structure, with thicknesses in the range of 10-100 nm (e.g. using microgram quantities of nanocrystal forming material), suitable for serial nanoelectron diffraction or microED.

As described above, some example embodiments of the present disclosure provide and/or employ a fluidic support structure that includes a plurality of lateral confinement structures that are configured to establish a spatially-separated set of nanocrystal growth regions, with each nanocrystal growth region having a lateral extent that is selected to limit the lateral size of nanocrystals, such that the combination of the submicron to micron solution thickness and the lateral confinement of the nanocrystal growth region limits the growth of seeded nanocrystals such that the nanocrystals grown within the nanocrystal growth regions have spatial dimensions that are sufficiently small for analysis via electron diffraction (without the need to fragment the grown nanocrystals).

Accordingly, lateral fluid confinement structures may be configured to limit the lateral dimension of the crystals to ensure that, across the device, a large number of spatially-separated crystals are generated, as opposed to a few large area crystals. The crystal area required will vary depending on application. In order to control crystal area during growth, the lateral spatial extent (e.g. diameter or effective diameter of a circular having an equivalent spatial area) of region enclosed or surrounded, at least in part, by a given lateral fluid confinement structure may be constrained to a range between 100 nm and several microns (e.g. 1, 2, 3, 4 or 5 microns), with lateral separations between adjacent lateral fluid confinement structures of 100 nm to several microns (e.g. 1, 2, 3, 4 or 5 microns). This structured surface breaks up flow and restricts crystal growth in the plane. This approach minimizes concentration gradients where one nucleation site upon reaching crystallization conditions cannot deplete the concentration of the target molecule and create just a few large crystals. This condition can be determined by the use of preformed picoliter wells (nanocrystal growth regions) of the corresponding diameter to create crystals of the desired cross-sectional area. An array of this picoliter wells can be fabricated with center-to-center distances of 1 to 10 microns to give >10⁶ crystals on a 1 cm platform for this crystallization chip concept.

It will be understood that nanowells are but one example of suitable lateral fluidic confinement structures, and that other lateral fluidic confinement structures may be employed in the alternative, provided that the lateral fluidic confinement structures define a plurality of nanocrystal growth regions, with each nanocrystal growth region being laterally bounded by one or more lateral fluidic confinement structures such that the growth of a nanocrystal within the nanocrystal growth region, after the nanocrystal growth region is locally energized to cause nucleation, is limited to spatial dimensions suitable for electron diffraction measurements, for example, to produce nanocrystals having a thickness in the range of 10-100 nm. Such an approach to nanocrystal formation can provide a homogeneous distribution of nucleation sizes and nanocrystal seeds to restrain crystal sizes and obtain nanocrystals spatially separated appropriately so that one nucleation site does not grow to the detriment of other crystals. In other words, the present example methods enable the controlled growth of spatially separated single nanocrystals, thereby ensuring that no one nanocrystal forms a large crystal structure that prevents growth of other nanocrystals, and with the spatial separation and lateral confinement of adjacent nanocrystals facilitating uniform crystal growth.

Such lateral fluidic confinement structures can be defined on the fluidic support structure such that each lateral fluidic confinement structure laterally encloses a respective nanocrystal growth region, such as in the case of a nanowell. However, in alternative example embodiments, a nanocrystal growth region may be partially laterally enclosed by a plurality of lateral fluidic confinement structures, such as a set of posts (e.g. pins or pillars) that surround an internal nanocrystal growth region. In such an example case, at least three post structures surround each nanocrystal growth region and are arranged to limit the growth of a nanocrystal within the nanocrystal growth region to have spatial dimensions suitable for electron diffraction. The lateral fluidic confinement structures may be formed from a material or coated with a material to limit the height of the solution within each nanocrystal growth region to a submicron to micron height (e.g. hydrophilic coating for aqueous born crystals). Due to capillary action, with appropriate surface treatment of pillar surfaces, the pillar height fixes the thickness of the liquid film and by keeping spacings large enough apart, can avoid “doming” of the liquid in these zones, which further leads to the pillar height defining the liquid thickness.

In some example implementations, the lateral fluidic confinement structures are defined such that each nanocrystal growth region has a common size, while in other example implementations, the lateral fluidic confinement structures are defined such that two or more nanocrystal growth regions have different sizes.

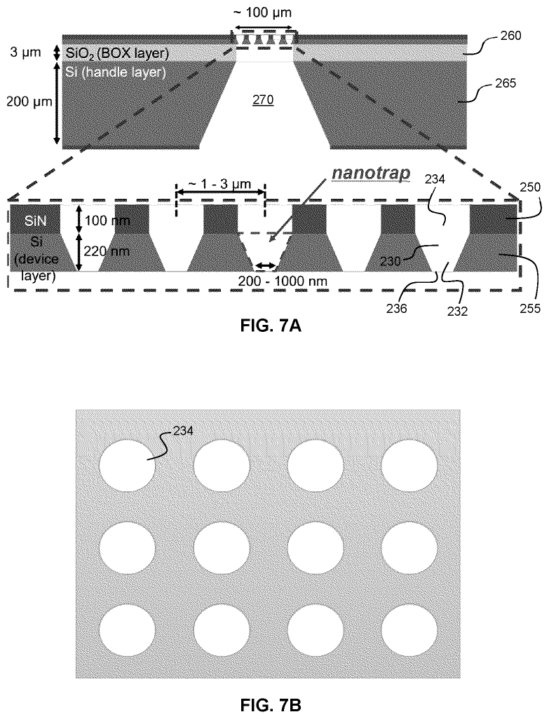

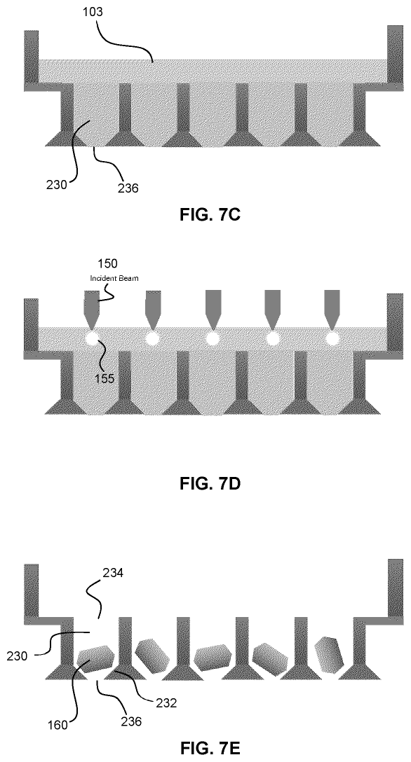

FIG. 7A shows a cross-sectional view of an example fluidic support structure (nanochip) that employs an array of nanowells (nanotraps) 230 to confine a solution and support the growth of nanocrystals with suitable dimensions for electron diffraction measurement. FIG. 7B shows a top view of the nanowell array including a plurality of nanowells 230, with expanded view shown in FIG. 7A. The nanowell array is mechanically supported by a lateral substrate 265, e.g. a silicon substrate as illustrated in the figure, with an overlying oxide layer shown as buried oxide (BOX) layer 260, e.g. formed from SiO₂ in this example embodiment, which can be readily etched to give preferred areas for liquid confinement with liquid deposition through 270 as the access port.

Within the mechanically suspended nanowell array region, the SiN layer 250 provides the first confinement of the nanowells in the vertical direction of growth and transport. The difference in composition of all the layers allows the use of differential etching methods to give the specific nanowell dimensions for targeted crystal growth. The final layer of the nanowell array, defined by 255, is shown to be fabricated from Si to enable use of standard anisotropic etching methods to create a truncated pyramid trap (having a trapezoid cross-sectional shape) for localizing crystals larger than the lateral dimension of the Si structure. The induced flow through this region by the application of suction leads to collisions of the crystal with the side walls of 250 and 255. The dimensions as shown are illustrative only. The height and width of all areas in 250 and 255 can be modified to accommodate different crystal morphologies to trap the nanocrystals while removing as much background solution as possible prior to introduction into the TEM environment.

The example nanochip shown in FIG. 7A include features that are used to trap nanocrystals and by turbulent flow attain random orientations. It is beneficial to have enough orientations/projections to determine the 3D structure from diffraction. The surface adhesion forces for such narrow channels on the nanoscale provides enough contact area and surface adhesion to trap nanocrystals at random orientations and minimizes the loss of nanocrystals in the removal of solvent in the aspiration process.

The example device shown in FIGS. 7A and 7B can be fabricated as follows, starting with a Si wafer 265. On one side of the wafer, a few hundreds of nanometer to a few micrometer thick SiO₂ 260, Si 255, and SiN 250 layers are deposited sequentially. Using electron beam lithography, the top SiN layer is patterned with the desired hole and pitch dimensions, considering the nanocrystal size and morphology. The exposed SiN layer is etched away using a fluoride-based gas ions. After then the SiO₂ and Si layers are chemically etched away using a fluoride-and ammonium-based etchant respectively, giving rise to an array composed of nanometer sized cavity 230 to be used for an efficient size selection and crystal trapping, with the Si layer being anisotropically etched to form a narrower lower base aperture to facilitate nanocrystal trapping, as noted above. The other side (backside) of the wafer is patterned with a photolithographic method to open up a clean region without photoresist. This region is chemically etched away using an ammonium-based etchant, resulting in an approximately 100 micrometer sized cavity 270.

FIGS. 7A and 7B illustrate an example fabricated implementation of a fluidic support structure. However, it will be understood that a wide variety of semiconductor materials and processing methods may be employed to fabricate a nanowell array with nanowells defined in a plurality of semiconductor layers, laterally supported by an underlying substrate (such as an semiconductor-on-insulator or buried oxide substrate), with the nanowells formed by an upper semiconductor layer etched to define an upper cylindrical portion of each nanowell, and a lower semiconductor layer anisotropically etched to define a lower truncated pyramid portion of each nanowell, thereby defining a lower aperture in each nanowell having dimensions suitable for trapping nanocrystals. This structure is not limited to Si nanofabrication methods that are well developed but can also be implemented with other semiconductor materials or patterning with Polydimethylsiloxane (PDMS) in a process known as soft lithography.

Many of the example methods of nanocrystal formation described herein involve the use of fluidic support structures with nanostructures that define laterally-separated regions, each having a thin layer of nanocrystal forming solution, and where the example methods involve the use of an energy beam to initiate nanocrystal nucleation and nanocrystal growth within the laterally-separated regions laterally surrounded or enclosed by the nanostructures (e.g. within a nanowell or within a region surrounded laterally by a local set of nanopillars). However, in other example methods, as illustrated in FIG. 7C, the nanocrystal forming solution may be delivered to the fluidic support structure such that a thin upper layer 103 of the nanocrystal forming solution, with a submicron to micron thickness, resides above a lower nanostructure array (shown in the figure as an array of nanowells 230), and where each confinement region of the nanostructure array (laterally enclosed, at least partially, by the nanostructures), includes a base region having an aperture 236 defined therein to facilitate aspiration.

As shown in FIG. 7D, prior to aspiration, while the thin upper layer 103 of the nanocrystal forming solution remains above the nanostructure array, and the energy beam 150 is delivered (e.g. scanned) among a plurality of spatially-separated locations within upper layer 103 of the nanocrystal forming solution, initiating nanocrystal nucleation at locations 155 and facilitating nanocrystal growth.

Subsequent aspiration of the residual solution, via the application of suction to the apertures 236 defined in the bottom portion of the nanostructure array, facilitates withdrawal of the residual solution and trapping of the nanocrystals 160 in the nanostructure array, as shown in FIG. 7E. The top openings 234 of the nanowells 230 (seen in the detail overhead view shown in FIG. 7B) enable nanocrystals with similar cross section area to enter the nanowell during aspiration to become trapped. The distribution of nanocrystals sizes will lead some crystals becoming trapped at angles in entering the channel to create random orientations. This opening is controllable, for example, from 20 nm to several microns, depending on crystal aspect ratio (thickness/area) to ensure a large fraction of nanocrystals as grown are trapped and minimize losses of crystals of smaller dimensions. In the example implementation shown in the figure (and as illustrated in the example implementation shown in FIG. 7A), the top opening 234 and lower truncated pyramid portion guide the crystals to the narrowest exit aperture 236 of the truncated pyramid 232, for example, to facilitate entrapment of nanocrystals having a desired thickness in the range, such as, for example, 10 nm to 200 nm, 20 nm to 200 nm, or 10 nm to 100 nm, by the spatial filtering process imposed by this tapered structure. The nanocrystals are driven by aspiration of solvent through this channel and orientation imposed by adhesion to the side walls defining the nanowell (nanopore), trapping the nanocrystals with random orientations.

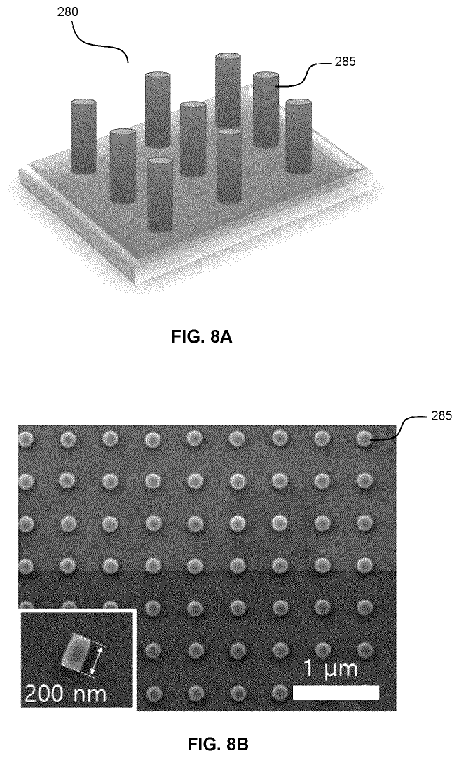

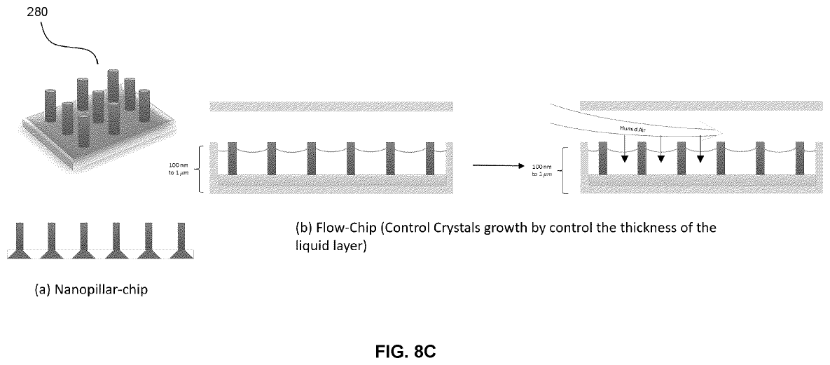

FIG. 8A shows an isometric view of an example nanopillar array 280, where the nanopillars 285 have a submicron to micron height configured to confine a submicron to micron layer of solution, and a spacing configured to support the growth of nanocrystals with suitable dimensions for electron diffraction measurement. FIG. 8B shows a top view of an example fabricated nanopillar array. FIG. 8C shows an example workflow for contacting a solution with a nanopillar array 280 of an example fluidic structure to form a submicron to micron solution thickness and the use of lateral vapour flow to control and/or maintain the solution height within the fluidic structure.

The height of the nanopillars fixes the liquid layer thickness and also serves to constrain crystal growth to the areas between pillars. As noted above, the present example is intended to serve as only one example embodiment, and the pillars could be replaced with other structures such as nanowells or nanoindents to serve the same purpose.

The bottom support layer may be sufficiently thin to permit electron transmission, such as approximately 10-50 nm thick. In some example implementations, the bottom window is sufficiently thin to allow maximum electron transmission for least background scatter to the diffraction pattern of interest. In this present example and others, excess liquid after crystal formation may be removed by blotting or vacuum aspiration, as with the window thickness condition, to have the least background electron scatter obscuring the diffraction pattern of interest.

While many of the preceding example embodiments refer to a fluidic support structure and associated methods for retaining a nanocrystal forming solution with a submicron to micron height, it will be understood that in other example embodiments, the fluidic support structure and associated methods are configured to retain a nanocrystal forming solution with a submicron height.

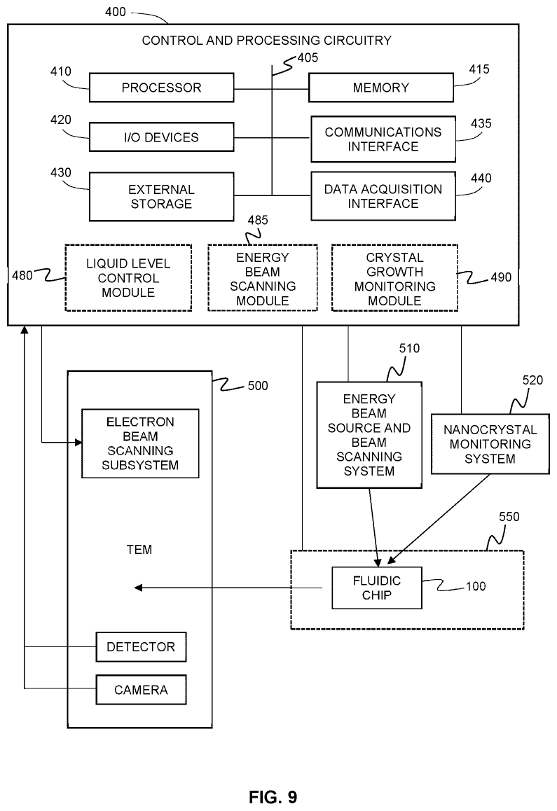

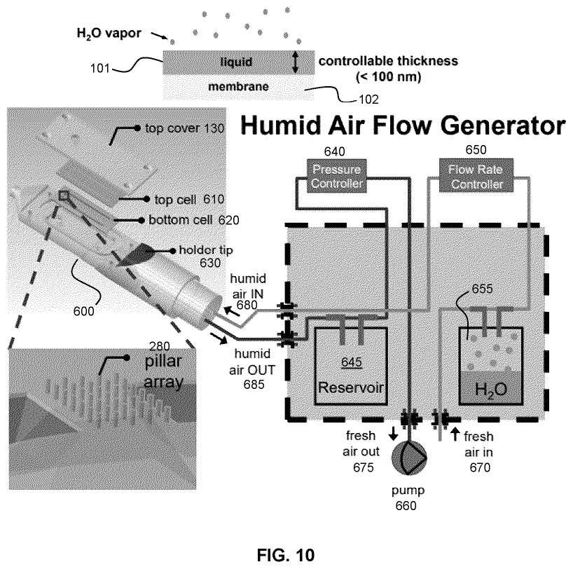

FIG. 9 illustrates an example system for fabricating nanocrystals within a fluidic structure that is suitable for subsequent TEM analysis. Control and processing system 400 is operatively coupled to the energy beam source and scanning system 510 (e.g. a femtosecond laser and associated scanning system involving motorized scanning mirrors and/or translation stages), an optional nanocrystal monitoring system 520, and an optional vapour flow control system 550. The control and processing circuitry 400 may also be interfaced with a TEM system 500 to control beam scanning and to receive and optionally process electron beam diffraction measurements. One or more components of the system, such as the nanocrystal monitoring system, may be integrated with the TEM 500.

As shown in the example embodiment illustrated in FIG. 9, the control and processing circuitry 400 may include a processor 410, a memory 415, a system bus 405, one or more input/output devices 420, and a plurality of optional additional devices such as communications interface 435, external storage 430, and data acquisition interface 440. In one example implementation, a display (not shown) may be employed to provide a user interface to facilitate work flow, and may further display data such as images of crystals, electron diffraction patterns, and results from crystal structure analyses.

The example methods described above can be implemented via processor 410 and/or memory 415. As shown in FIG. 9, executable instructions represented as liquid level control module 480, energy beam scanning module 485 and crystal growth monitoring module 490 are processed by control and processing circuitry 400. The control and processing circuitry 400 may include, for example, and execute instructions for performing one or more of the methods described herein, or variants thereof. Such executable instructions may be stored, for example, in the memory 415 and/or other internal storage.

The methods described herein can be partially implemented via hardware logic in processor 410 and partially using the instructions stored in memory 415. Some embodiments may be implemented using processor 410 without additional instructions stored in memory 415. Some embodiments are implemented using the instructions stored in memory 415 for execution by one or more microprocessors. Thus, the disclosure is not limited to a specific configuration of hardware and/or software.

It is to be understood that the example system shown in the figure is not intended to be limited to the components that may be employed in a given implementation. For example, the system may include one or more additional processors. Furthermore, one or more components of control and processing circuitry 400 may be provided as an external component that is interfaced to a processing device. Furthermore, although the bus 405 is depicted as a single connection between all of the components, it will be appreciated that the bus 405 may represent one or more circuits, devices or communication channels which link two or more of the components. For example, the bus 405 may include a motherboard. The control and processing circuitry 400 may include many more or less components than those shown. In some example implementations, some aspects of the data processing may be performed using an additional external computing system, such as the processing of the electron diffraction pattern images for the determination of crystal structure.

Some aspects of the present disclosure can be embodied, at least in part, in software, which, when executed on a computing system, transforms an otherwise generic computing system into a specialty-purpose computing system that is capable of performing the methods disclosed herein, or variations thereof. That is, the techniques can be carried out in a computer system or other data processing system in response to its processor, such as a microprocessor, executing sequences of instructions contained in a memory, such as ROM, volatile RAM, non-volatile memory, cache, magnetic and optical disks, or a remote storage device. Further, the instructions can be downloaded into a computing device over a data network in a form of compiled and linked version. Alternatively, the logic to perform the processes as discussed above could be implemented in additional computer and/or machine-readable media, such as discrete hardware components as large-scale integrated circuits (LSI's), application-specific integrated circuits (ASIC's), or firmware such as electrically erasable programmable read-only memory (EEPROM's) and field-programmable gate arrays (FPGAs).

A computer readable storage medium can be used to store software and data which when executed by a data processing system causes the system to perform various methods. The executable software and data may be stored in various places including for example ROM, volatile RAM, nonvolatile memory and/or cache. Portions of this software and/or data may be stored in any one of these storage devices. As used herein, the phrases “computer readable material” and “computer readable storage medium” refers to all computer-readable media, except for a transitory propagating signal per se.

FIG. 10 illustrates an example environmental control subsystem for controlling and maintaining a desired solution level within the fluidic support structure to facilitate the growth of nanocrystals with dimensions suitable for electron diffraction. This example design is implemented with a nanopillar array, 280, configured such that the liquid layer height of the nanocrystal-forming solution is determined by the pillars, but it will be understood that the present example is illustrative and not intending to be limited to such a structure.

As shown in the figure, the device is a fluidic support structure provided in the form of a crystal growth chamber that housed in a housing 600 is enclosed by a top cover 130, a top cell structure 610 and a bottom cell layer 620, housed within the tip region 630 of the housing 600. The top cover 130 can be both transparent to electrons and laser irradiation for seeding crystal growth. For example, in one example implementation, the top cover 130 could be made of a SiN window less than 20 nm thick for sufficient electron transmission for viewing crystal growth, while also being optically transparent for laser seeding nanocrystal growth.

The example embodiment shown in the figure facilitates the controlled evaporation of a liquid (nanocrystal-forming solution) 101 under gas flow for which the liquid is in contact with a membrane 102 that supports the nanopillar array and provides sufficiently high surface adhesion to create a thin layer of liquid for forming nanocrystals. This illustrated apparatus facilitates control of the evaporation of the liquid layer by adjusting the flow of solvent vapor, which in this case is shown as water vapor, but can be any solvent vapor for which the material of interest is soluble. Under humid air flow, or other solvent, the liquid layer thickness is controllable by adjusting the flow from a solvent reservoir 655 through a control valve (solvent flow rate controller) 650 using a fresh air inlet 670 mixed with the water vapor from reservoir 655, using a micropump 660 with exit air outlet 675 in the pumping circuit. Pressure control may optionally be provided by a pressure control valve 640 that measures and optionally controls the pressure exiting the crystal growth chamber. The example apparatus shown in the figure includes an optional output reservoir for reducing the humidity in the air that is exhausted from the apparatus at port 675.

The flow rate, as prescribed and controlled by the flow rate controller 650 provides control over the degree of vapor pressure entering the crystal growth cell, which in turn controls the liquid exchange and condensation of the liquid layer in the crystal growth chamber. In some example implementations, the thickness of the layer of the nanocrystal forming solution retained within the crystal growth cell (the fluidic support structure) can be determined based on in-situ TEM analysis, with the housing 600 and crystal growth cell residing in a TEM. For example, in some example implementations, the electron transmittance, or another measure of transmission, may be employed (e.g. through calculation/simulation or correlation with reference measurements) to determine the thickness of the layer of nanocrystal forming solution. In other example implementations, the contrast of one or more features in a TEM image of the nanostructure region may be employed to determine when a desired thickness of the nanocrystal forming solution has been achieved. In other example implementations, a signal from another sensor, such as a vapour pressure sensor (not shown in the figure) may be employed to infer a thickness of the nanocrystal forming solution, for example, based on a pre-established relationship between nanocrystal forming solution thickness and sensor signal.

With the ability to vary the flow and/or degree of humidity or vapor saturation, control of the thickness of the layer of the nanocrystal forming solution retained on the fluid support structure has been demonstrated to with 10-20 nm resolution with 100 nm to micron layer thickness achievable within this thickness (height) resolution. It has been found that confining the layer of the nanocrystal forming solution to a submicron to micron thickness further confines the thickness of growing nanocrystals growth to the 10-100 nm scale that is suitable for electron diffraction for both cases. As shown in the figure, and as noted above, the nanopillar array 280 can be employed to further confine/define the liquid layer thickness for growing nanocrystals. The use of differential flow and degree of vapor saturation enables control of the liquid layer beyond that possible with the fixed nanopillar structure of FIG. 8.

As noted above, the present examples of fluidic support structures are configured to be compatible with a TEM, such that nanocrystals formed in the fluidic support structures may be directly interrogated via electron diffraction in situ, without requiring transport to a different TEM support. It will be understood that there are many different designs and material platforms that can facilitate TEM compatibility.

In one example implementation, a fluidic support structure for supporting a thin solution to facilitate the formation of spatially separated nanocrystals could be made from semiconductor (e.g. Si) supports that are integrated or contacted with a bottom window that forms a bottom layer of the device, where the window has a material and thickness suitable for performing electron diffraction analysis. Examples of materials suitable for the window include SiN, graphene, and boron nitride (BN). As noted above, the device may also include an upper window that can also be formed from such materials. In another example implementation, the bottom layer of the device can be formed from a standard carbon coated TEM grid (quantafoil).

In an example embodiment involving a nanopillar array, the template used to make the nanopillars could also be made from PMMA printing for the pillars, for example, could be micron diameter, of suitable dimensions that spin coating, a means to selective deposit coatings based on centripetal force to thin the layers, could be performed to control height from 100 nm to several microns with 100 nm resolution. The resulting nanopillars made with standard photolithography to define the support structure with the nanopillars forming the bottom layer and have the same structure as a TEM grid with small enough grid features for holding the crystals and presenting the crystals to the electron beam, in such a manner to allow electron transmission through the crystal for electron diffraction, without blocking the electrons by the grid support for the crystals. Such a structure could be fabricated, for example, by the same means used above in discussion of the spatial filter for trapping nanocrystals. This structure will generally be intended to use directly in the TEM.

The present disclosure provides methods of nanocrystal formation that are compatible with the use of lab-on-a-chip technology with substantially less materials, improved safety, and with less venting of materials to the environment. The use of such methods, in combination with the direct nanocrystal growth and electron diffraction methods disclosed herein, can enable a significant increase in the speed and efficiency in development of new materials for drugs and functionalized materials from active devices to agricultural products. Indeed, the entire chemical stock room could effectively be miniaturized onto a master source chip with picoliter wells with microvalves to flow chemicals from different ports to a mixing chamber and microscale heaters as needed. The volumes employed may be sufficiently small that uniform mixing is ensured. Purification steps involving liquid chromatography or other separation methods can be included in-line requiring order of magnitude less path length and column material to provide a purified output of a particular step to serve as the input to second reaction step, and so forth, with the overall synthesis finally ending at the final product output port in a form that can be directly employed as the solution containing the nanocrystal forming material for use with the embodiments disclosed herein to grow nanocrystals suitable for direct electron diffraction for structural analysis.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

1. A method of fabricating nanocrystals suitable for electron diffraction analysis, the method comprising:
contacting a fluidic support structure with a solution containing a nanocrystal forming material, such that the solution is retained on the fluidic support structure; and
delivering an energy beam to the solution retained on the fluidic support structure at a plurality of laterally spaced regions, the energy beam being configured to locally induce nucleation and nanocrystal growth within the solution, such that within at least one region of the plurality of laterally spaced regions, nanocrystal nucleation and growth is initiated;
wherein the fluidic support structure is configured such that the solution retained thereon is sufficiently thin such that nanocrystals formed within the solution have a submicron thickness suitable for analysis by electron diffraction.

2. The method according to claim 1 further comprising:
employing a transmission electron microscope to perform electron diffraction measurements on at least one nanocrystal supported by the fluidic support structure.

3. The method according to claim 2 wherein the fluidic support structure is directly employed within the transmission electron microscope for the electron diffraction measurements in the absence of nanocrystal transfer to a separate transmission electron microscope support.

4. The method according to claim 2 further comprising employing the electron diffraction measurements to infer an atomic structure of the at least one nanocrystal.

5. The method according to claim 1, wherein the fluidic support structure is configured to retain the solution thereon with a sufficiently thin layer such that nanocrystals formed within the solution have a thickness between 10 nm and 100 nm.

6. The method according to claim 1, wherein the fluidic support structure is configured such that the solution is retained with a submicron to micron thickness.

7. The method according to claim 1, wherein the fluidic support structure is configured such that the solution is retained with a submicron thickness.

8. The method according to claim 1, wherein a solvent vapour is flowed over the solution retained on the fluidic support structure.

9. The method according to claim 8 wherein at least one of a flow rate and a vapour pressure of the solvent vapour is controlled to maintain a thickness of the solution retained on the fluidic support structure.

10. The method according to claim 8 wherein at least one of a flow rate and a vapour pressure of the solvent vapour is controlled to maintain a solubility point of the solution retained on the fluidic support structure at supersaturation.

11. The method according to claim 1, wherein the fluidic support structure comprises a plurality of lateral fluid confinement structures provided such that each laterally spaced region is at least partially laterally enclosed, and such that nanocrystal growth is spatially confined within each laterally spaced region.

12. The method according to claim 11 wherein the plurality of lateral fluid confinement structures comprise a plurality of nanowells.

13. The method according to claim 12 wherein each nanowell comprises a base region having an aperture defined therein, and wherein a vacuum aspiration subsystem is interfaced with the fluidic support structure to aspirate solvent through respective apertures of each nanowell.

14. The method according to claim 11 wherein the plurality of lateral fluid confinement structures comprise a nanopillar array.

15. The method according to claim 11, wherein the plurality of lateral fluid confinement structures are configured such that each laterally spaced region has an effective diameter between 100 nm and 5 microns.

16. The method according to claim 11, wherein adjacent laterally spaced regions are separated by 100 nm to 5 microns.

17. The method according to claim 1, wherein the energy beam is configured to generate bubbles within the solution increasing locally the concentration of solution for initiating nanocrystal nucleation.

18. The method according to claim 1, wherein the energy beam is configured such that absorption of the energy beam causes superheating and rapid evaporation to facilitate nanocrystal nucleation and growth.

19. The method according to claim 1, wherein the energy beam comprises a plurality of laser pulses.

20. The method according to claim 19 wherein the laser pulses are femtosecond laser pulses.

21. The method according to claim 19 wherein the energy beam comprises infrared laser pulses having a pulse duration less than a thermal diffusion limited cooling time of a solvent of the solution.

22. The method according to claim 19 wherein the fluidic support structure is configured to absorb the laser pulses and generate heat sufficient for superheating the solution.

23. The method according to claim 1, wherein the energy beam is an electron beam.

24. The method according to claim 1, further comprising:
directing a probe energy beam onto the plurality of laterally spaced regions, the probe energy beam being configured to generate a signal in the presence of nanocrystals; and
employing the signal to monitor nanocrystal growth within the laterally spaced regions.

25. The method according to claim 24 further comprising:
detecting the signal from a given laterally spaced region; and
continuing to deliver the energy beam to the given laterally spaced region until the signal satisfies pre-determined criteria associated with a sufficiency of nanocrystal size for electron diffraction analysis.

26. The method according to claim 24 further comprising:
detecting an absence of the signal from a given laterally spaced region; and
repeating the delivery of the energy beam to the given laterally spaced region.

27. The method according to claim 1, further comprising:
directing a probe energy beam onto the plurality of laterally spaced regions, the probe energy beam being configured to generate a signal in the presence of nanocrystals;
employing the signal to identify laterally spaced regions containing nanocrystals having a size suitable for electron diffraction; and
interrogating the identified laterally spaced regions via transmission electron microscopy.

28. The method according to claim 1, further comprising subjecting the fluidic support structure to plunge freezing prior to performing transmission electron microscopy.

29. The method according to claim 1, wherein the fluidic support structure comprises a TEM grid.

30. A system for fabricating nanocrystals suitable for electron diffraction analysis, the system comprising:
a fluidic support structure;
a means for generating and delivering an energy beam to a plurality of laterally spaced regions of said fluidic support structure, the energy beam being configured to locally induce nucleation and nanocrystal growth within a solution containing a nanocrystal forming material when the solution is retained on said fluidic support structure;
said fluidic support structure being capable of retaining the solution thereon with a sufficiently thin layer such that nanocrystals formed within the solution have a submicron thickness suitable for analysis by electron diffraction.

31. A method of fabricating nanocrystals suitable for electron diffraction measurement, the method comprising:
contacting a fluidic support structure with a solution containing a nanocrystal forming material, such that the solution is retained on the fluidic support structure with a submicron solution thickness;
delivering an energy beam to a plurality of spatially-separated locations within the solution retained on the fluidic support structure, the energy beam being configured to locally induce nucleation and nanocrystal growth within the solution, such that for at least two of said plurality of spatially-separated locations, a respective nanocrystal having a submicron thickness is formed; and
employing a TEM to perform electron diffraction measurements on at least one nanocrystal residing on the fluidic support structure.
